(19) United States
(12) Patent Application Publication
(10) Pub. No.: US 2024/0047207 A1
(43) Pub. Date: Feb. 8, 2024

(54) Technique for Forming Cubic Silicon Carbide and Heterojunction Silicon Carbide Device

(71) Applicant: Infineon Technologies AG, Neubiberg (DE)

(72) Inventors: Christian Zmoelnig, Villach (AT); Tobias Franz Wolfgang Hoechbauer, Villach (AT); Andreas Voerckel, Finkenstein (AT); Hans Weber, Bayern (DE)

(21) Appl. No.: 17/879,460

(22) Filed: Aug. 2, 2022

(51) Int. Cl. H01L 21/02; H01L 29/04; H01L 29/16; H01L 29/778; C30B 25/20; C30B 23/02; C30B 29/36; C30B 29/68

(52) U.S. Cl. CPC H01L 21/02609; H01L 21/02378; H01L 21/0243; H01L 21/02529; H01L 29/045; H01L 29/1608; H01L 29/7786; C30B 25/20; C30B 23/025; C30B 29/36; C30B 29/68

(57) ABSTRACT

A method of forming a semiconductor device includes providing a base substrate comprising SiC and a growth surface extending along a plane that is angled relative to a first crystallographic plane of the SiC from the base substrate, forming first and second trenches in the base substrate that extend from the growth surface into the base substrate, epitaxially forming a first SiC layer on the growth surface of the base substrate by a step-controlled epitaxy technique, and epitaxially forming a second SiC layer on the first SiC layer, wherein the first SiC layer is a layer of α-SiC, and wherein the second SiC layer is a layer of β-SiC.

### BACKGROUND

Power semiconductor devices are typically used as switches and rectifiers in electric circuits for transforming electrical energy, for example, in DC/AC converters, AC/AC converters or AC/DC converters, and in electric circuits that drive heavy inductive loads, e.g., in motor driver circuits. Silicon carbide (SiC) technology represents a popular choice for many power semiconductor devices due to its favorable electrical properties. In particular, SiC material has a higher bandgap in comparison to other semiconductor materials such as silicon, which allows for higher voltage ratings and/or current switching capability. Silicon carbide substrates or films with a cubic crystal structure, i.e., so-called “3C-SiC”, are particularly desirable, since 3C-SiC offers improved electrical performance in comparison to hexagonal polytypes of SiC, e.g., so-called 4H-SiC, 6H-SiC, etc. However, current methods for forming 3C-SiC are economically infeasible, incapable of forming high quality material with a low defect density, or both.

### SUMMARY

A method of forming a semiconductor device is disclosed. According to an embodiment, the method comprises providing a base substrate comprising SiC and a growth surface extending along a plane that is angled relative to a first crystallographic plane of the SiC from the base substrate, forming first and second trenches in the base substrate that extend from the growth surface into the base substrate, epitaxially forming a first SiC layer on the growth surface of the base substrate by a step-controlled epitaxy technique, and epitaxially forming a second SiC layer on the first SiC layer, wherein the first SiC layer is a layer of α-SiC, and wherein the second SiC layer is a layer of β-SiC.

A semiconductor device is disclosed. According to an embodiment, the semiconductor device comprises a silicon carbide substrate comprising a first SiC layer and a second SiC layer formed on an upper surface of the first SiC layer, wherein the first SiC layer is a layer of α-SiC, wherein the second SiC layer is a layer of β-SiC, and wherein the upper surface of the first SiC layer is aligned with a first crystallographic plane of the SiC from the first SiC layer.

### BRIEF DESCRIPTION OF THE FIGURES

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a base substrate with first and second trenches formed in a growth surface of the base substrate, according to an embodiment.

FIG. 2 schematically illustrates an epitaxy process that forms a first SiC layer on the growth surface of the base substrate by a step-controlled epitaxy technique and a second SiC layer on the first SiC layer, according to an embodiment.

FIG. 3 illustrates a semiconductor substrate with a completed first SiC layer and completed second SiC layer formed on the base substrate, according to an embodiment.

FIG. 4 illustrates a semiconductor device that comprises a heterojunction between a first SiC layer and a second SiC layer, according to an embodiment.

### DETAILED DESCRIPTION

Described herein are methods for forming substantially defect-free 3C-SiC (cubic silicon carbide) by an epitaxy process. The method comprises using a step-controlled epitaxy technique to form a layer of α-SiC, e.g., 2H-SiC, 4H-SiC, 6H-SiC, etc., on a base substrate that comprises SiC of the same polytype. The base substrate comprises a growth surface that extends along a tilted plane relative to the crystallographic plane of the underlying semiconductor material. For example, the growth surface may be oriented at 4° in the [11-20] direction relative to the (0001) lattice plane of the underlying semiconductor material. Such a titled growth surface provides well-defined steps and terraces that facilitate the growth of hexagonal silicon carbide by a step-controlled epitaxy technique. The SiC base substrate additionally comprises trenches that are formed in the growth surface and extend transversely with the growth direction with the hexagonal silicon carbide formed by the step-controlled epitaxy technique. The trenches interrupt the steps and terraces in the growth surface of the base substrate. This influences the step-controlled epitaxy to create a transitional surface of the hexagonal silicon carbide that originates at a corner of the trench, wherein SiC forms in the thermodynamically favorable 3C-SiC over this transitional surface. Substantially thick films of monocrystalline 3C-SiC can be formed using this technique in a cost-effective manner. In an embodiment, a semiconductor device is provided using the monocrystalline 3C-SiC to form an active device region.

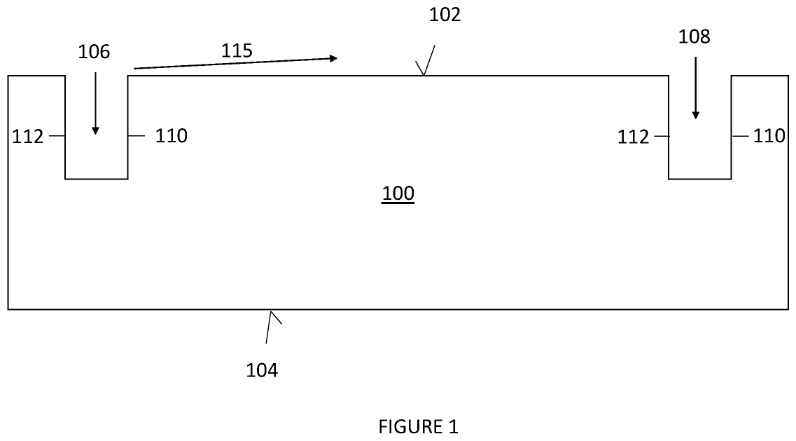

Referring to FIG. 1, a method of forming a semiconductor device comprises providing a base substrate 100. The base substrate 100 is a semiconductor substrate that is used to grow SiC (silicon carbide) by an epitaxy process. The base substrate 100 comprises SiC material in at least a region that extends to a growth surface 102. This SiC material of the base substrate 100 can be any type of α-SiC. According to an embodiment, the base substrate 100 comprises any one of: 2H-SiC, 4H-SiC, and 6H-SiC extending to the growth surface 102. The base substrate 100 may be provided from a commercially available SiC wafer. Alternatively, the base substrate 100 may be provided by epitaxially forming SiC material and cutting or otherwise detaching the SiC material into a wafer.

The base substrate 100 comprises a growth surface 102 opposite from a rear surface 104 of the base substrate 100. The growth surface 102 extends along a plane that is angled relative to a first crystallographic plane of the SiC from the base substrate 100 that extends to the growth surface 102. That is, the growth surface 102 does not align with one of the natural crystallographic lattice planes of the crystalline material within the base substrate 100. Instead, the growth surface 102 is intentionally formed, e.g., by cutting, to extend at an angle that is non-parallel and non-perpendicular to the first crystallographic plane of the SiC. The angle and first crystallographic plane can be selected to provide well-defined terraces and steps in the growth surface 102 that are suitable for a step-controlled epitaxy technique, the details of which will be described below. In principle, the first crystallographic plane of the SiC can be any lattice plane of the crystalline material within the base substrate 100. According to an embodiment, the first crystallographic plane is the (0001) plane, and the growth surface 102 is oriented at an angle of between 2° and 6° relative to the [11-20] lattice direction. In a particular embodiment, the first crystallographic plane is the (1000) lattice plane and the growth surface 102 is oriented at an angle of 4° relative to the [11-20] lattice direction.

The base substrate 100 comprises first and second trenches 106, 108 that extend from the growth surface 102 into the base substrate 100. The first and second trenches 106, 108 are intentionally formed features in the base substrate 100 that comprise first and second sidewalls 110, 112 intersecting the growth surface 102 and extending towards the rear surface 104. The first and second trenches 106, 108 can be formed by a variety of different techniques, e.g., etching techniques, mechanical grinding, drilling, etc. The first and second trenches 106, 108 can be representative of a unit-cell pattern that may be repeated multiple times in the base substrate 100. That is, the base substrate 100 may comprise any number of the trenches, e.g., three, five, ten, twenty, etc., wherein each of these trenches may have the same geometric properties and spacing distance as the first and second trenches 106, 108. As will be explained in further detail below, the methods disclosed herein comprise forming a first SiC layer 114 on the growth surface of the base substrate 100 by a step-controlled epitaxy technique, wherein the first SiC layer 114 forms in a growth direction 115. In this disclosure, the term first trench 106 refers to the trench that the first SiC layer 114 grows away from in the growth direction 115 and the term second trench 108 refers to the trench that the first SiC layer 114 grows towards in the growth direction 115. It will be appreciated that this process can occur simultaneously between any two pairs of trenches such that the first and second trenches 106, 108 may serve the opposite role relative to immediately adjacent trenches (not shown).

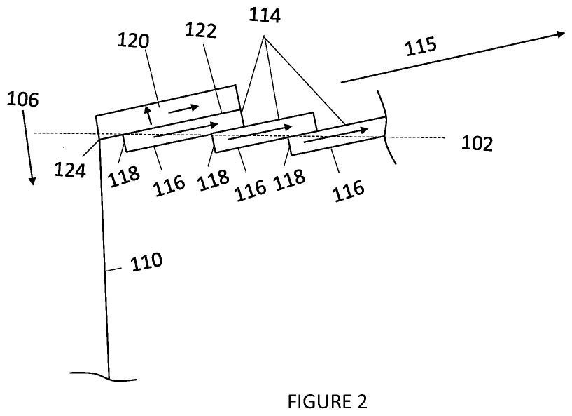

Referring to FIG. 2, an epitaxial deposition process is formed on the base substrate 100. FIG. 2 schematically illustrates how the epitaxial deposition process behaves in the vicinity the first trench 106. The figure depicts terraces 116 and steps 118 formed in the growth surface. These terraces 116 and steps 118 result from the angled cut of the growth surface 102 relative to the first crystallographic plane, wherein each terrace 116 corresponds to a surface that extends along the first crystallographic plane and each step 118 corresponds to a transition between SiC bilayers. Thus, the angled cut of the growth surface 102 reveals the stacking sequence of the SiC material from the base substrate. It should be appreciated that FIG. 2 is merely a schematic illustration of the concept, and the proportional relationships from this figure are not necessarily accurate.

According to the method, a first SiC layer 114 is formed on the growth surface 102 of the base substrate 100 by a step-controlled epitaxy technique. A step-controlled epitaxy technique, which is also referred to a step-flow growth technique, is disclosed in “Step-controlled epitaxial growth of SiC: High quality homoepitaxy,” Matsunami, Hiroyuki, and Kimoto, Materials Science and Engineering: R: Reports 20.3 (1997), the content of which is incorporated by reference herein in its entirety, and in “Fundamentals of Silicon Carbide Technology” Kimoto et al., (2014), the content of which is incorporated by reference herein in its entirety. To briefly summarize, this technique involves providing a surface of SiC material that is cut along an off-axis plane to comprise a high density of steps 118 and terraces 116, e.g., as explained above. Epitaxial deposition of SiC is performed using epitaxy processes such as chemical vapor deposition (CVD) and/or sublimation epitaxy. Due to the step and terrace geometry of the growth surface 102, the SiC grows in a lateral direction away from the steps 118, which is referred to as the growth direction 115 in this disclosure. The steps 118 provide the necessary information for the stacking of the SiC bilayers such that the material formed by step-flow growth retains the polytype of the material at the underlying growth surface 102, i.e., the material forms homoepitaxially. Thus, the first SiC layer 114 may form as a layer of α-SiC that replicates the polytype of the underlying α-SiC of the base substrate 100, e.g., 2H-SiC, 4H-SiC, 6H-SiC, etc.

According to the method, a second SiC layer 120 is formed on the first SiC layer 114. The second SiC layer 120 forms heteroepitaxially as a layer of β-SiC i.e., so-called 3C-SiC. The reason for this is due to the influence of the first sidewall 110 on the growth surface 102. This first sidewall 110 interrupts the step and terrace geometry in the growth surface 102 such that one of the terraces 116 (leftmost in the figure) intersects the first sidewall 110 instead of adjoining the next step 118. By interrupting the next step 118, the epitaxial material that originates from this point grows in the thermodynamically favorable 3C-SiC crystal structure. The first SiC layer 114 comprises an upper surface 122 that is aligned with the first crystallographic plane and originates at the first corner 124 of the first trench 106. In this context, the description that the upper surface 122 originates at the first corner 124 of the first trench 106 accounts for a small gap that may occur between the upper surface 122 and the first corner 124 of the first trench 106 due to crystallographic transitions. From this location on, material is not forced by the off-axis surface to grow in the same crystal structure as the subjacent substrate and instead forms in the 3C-SiC crystal structure. The second SiC layer 120 thus forms in a direction orthogonal to the growth direction 115, as the SiC bilayers vertically stack on top of one another according to the 3C-SiC stacking sequence. Additionally, the second SiC layer 120 forms along the upper surface 122 of the first SiC layer 114 as the first SiC layer 114 expands in the growth direction 115.

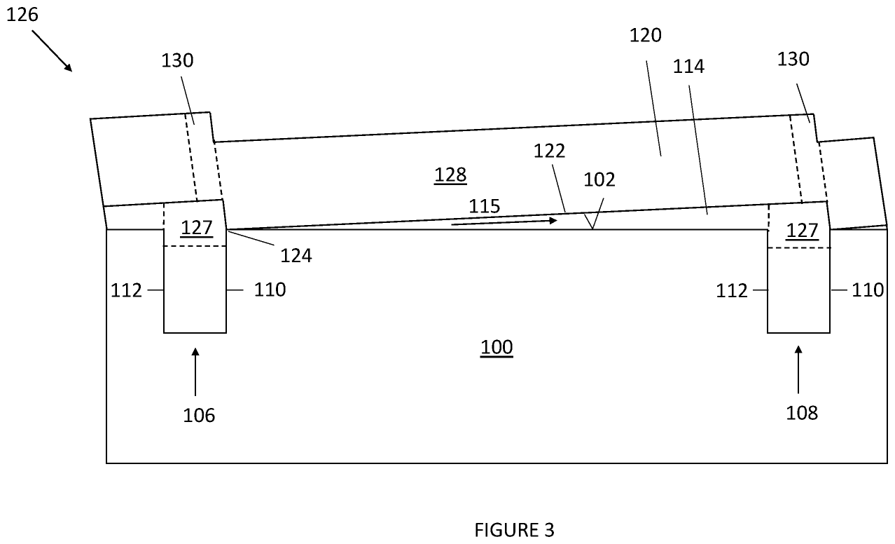

Referring to FIG. 3, a semiconductor substrate 126 is shown after completion of the epitaxial deposition process as described above. The figure shows the formation of the first SiC layer 114 and the second SiC layer 120 in a cross-sectional region comprising the first and second trenches 106, 108, with similar growth occurring in regions that are on either lateral side of the first and second trenches 106, 108 wherein further trenches (not shown) may be arranged on either lateral side of the first and second trenches 106, 108. The epitaxial deposition process is performed such that the first SiC layer 114 covers the growth surface 102 of the base substrate 100 in between the first and second trenches 106, 108. Moreover, the first SiC layer 114 is formed to at least partially fill the first and second trenches 106, 108. This process creates the second SiC layer 120 on the upper surface 122 of the first SiC layer 114 so as to cover the first SiC layer 114. This is done by performing the step-controlled epitaxy technique such that the uppermost layer of the first SiC layer 114 reaches the second trench 108. Due to the off-axis cut of the growth surface 102 and the influence of the first trench on the step-controlled epitaxy technique, the first SiC layer 114 becomes increasingly thicker as it forms in the growth direction between the first trench 106 and the second trench 108, wherein the angle between the lower side of first SiC layer 114 interfacing with the growth surface 102 and the upper surface 122 of the first SiC layer 114 corresponds to the angle difference between the growth surface 102 and the first crystallographic plane.

Epitaxially forming the first SiC layer 114 may form defect regions 127 within or above the first and second trenches 106, 108. In these defect regions 127, the SiC material may have a polycrystalline or amorphous crystal structure. This is due to the lattice mismatching and convergence of the first SiC layer 114 as the step-flow grown material spills into the first and second trenches 106, 108. Separately or in combination, voids may form in these defect regions 127, due to the growth pattern of the step-flow grown material within the first and second trenches 106, 108. Separately or in combination, the semiconductor material in the defect regions 127 may be monocrystalline material with a high density of dislocations and/or other crystal defects.

The second SiC layer 120 is formed on the first SiC layer 114 to comprise a monocrystalline region 128 of the β-SIC. The monocrystalline region 128 is disposed directly on the upper surface of the first SiC layer 114 and is laterally between the first and second trenches 106, 108. This second SiC layer 120 is formed by exhausting the growth of the first SiC layer 114 such that the first SiC layer 114 covers the growth surface 102 of the base substrate 100 in between the first and second trenches 106, 108 and fills the first and second trenches 106, 108 in the manner describes above. By exhausting the growth of the first SiC layer 114, a complete layer of the β-SiC is formed thereon. In principle, the epitaxy process can be carried out increase the thickness of the second SiC layer 120 as desired.

The monocrystalline region 128 of β-SiC is section of substantially defect free β-SiC with advantageous electrical characteristics that are well-suited for active device formation. Due to the defect regions 127 that form in the subjacent material, some crystalline defects may propagate into regions 130 of the second SiC layer 120 that are above the first and second trenches 130. The process disclosed herein advantageously relegates this defect formation to these regions 130 in a reliable manner, with the monocrystalline regions 128 of substantially defect free β-SiC material being reliably formed in between these regions. The trench concept disclosed herein can be used to provide numerous monocrystalline regions 128, e.g., in the form of an array, with each of these monocrystalline regions 128 being interposed between regions 130 that are not used for device formation.

The methods described herein may comprise selecting geometric parameters of the first and second trenches 106, 108 to influence the attributes of the first and/or second layers of SiC material 114, 130 and obtain preferred or advantageous characteristics for the monocrystalline region 128 of β-SiC. Examples of geometric parameters that may be selected to obtain preferred or advantageous characteristics include the width of the first and second trenches 106, 108, the cross-sectional area of the first and second trenches 106, 108, the volume of the first and second trenches 106, 108, the lateral separation distance between the first and second trenches 106, 108, and the orientation of the first and second sidewalls 110, 112 in the first and second trenches 106, 108 relative to the direction 115 and/or relative to the growth surface 102.

In one example of selecting geometric parameters of the first and second trenches 106, 108, the size parameters of the first and second trenches 106, 108 are selected to control defect formation and/or void formation of the SiC material. The size parameters of the first and second trenches 106, 108 may comprise the width of the first and second trenches 106, 108 from a cross-sectional perspective perpendicular to the growth direction 115, the area of the first and second trenches 106, 108 from a cross-sectional perspective perpendicular to the growth direction 115, and the overall volume of the first and second trenches 106, 108. If the size of the first and second trenches 106, 108 is made too large, significant void formation may occur within and above the first and second trenches 106, 108, e.g., in the defect regions 127. Conversely, if the size of the first and second trenches 106, 108 is made too small, defects may propagate out of the lateral boundaries of the first and second trenches 106, 108. Thus, selecting geometric parameters of the first and second trenches 106, 108 may comprise determining values that provide the appropriate balance between the two. Separately or in combination, the geometric parameters of the first and second trenches 106, 108 may selected based upon the type of epitaxial process performed, e.g., chemical vapor deposition (CVD) sublimation epitaxy, etc.

In another example of selecting geometric parameters of the first and second trenches 106, 108, a lateral spacing distance in the growth direction 115 between the first and second trenches 106, 108 may be selected. In principle, the size of monocrystalline region 128 of β-SiC can be increased by increasing the lateral separation distance between the first and second trenches 106, 108 in the growth direction 115 of the α-SiC. However, because the first SiC layer 114 becomes gradually thicker with increasing separation distance between the first and second trenches 106, 108, a larger separation distance between the first and second trenches 106, 108 requires further time to exhaust the growth of the α-SiC hence growth of a greater volume of α-SiC before a complete layer of the β-SiC can be formed. Thus, designers may select a lateral spacing distance between the first and second trenches 106, 108 to balance a tradeoff between these considerations.

In another example of selecting geometric parameters of the first and second trenches 106, 108, the geometry of the first and second sidewalls 110, 112 from the first and second trenches 106, 108 may be tailored. As explained above, the β-SiC from the second SiC layer 120 results from the formation of an acute corner with the growth surface 102 that disrupts the step-shaped geometry of the first and second trenches 106, 108. In principle, the β-SiC can be realized with any acute change in the growth surface 102, i.e., a surface that is non-parallel and non-perpendicular to the growth direction 115. According to embodiments, the first sidewall 110 which forms the first corner 124 is within +/−30 degrees of perpendicular to the growth direction 115, e.g., within +/−20 degrees of perpendicular to the growth direction 115, within +/−10 degrees of perpendicular to the growth direction 115, or within +/−5 degrees of perpendicular to the growth direction 115. The second sidewalls 112 of the first and second trenches 106, 108 are not used to create the β-SiC in the same way. Thus, the orientation of second sidewalls 112 are not necessarily the same as the first sidewalls 110, and may be tailored for other considerations, e.g., minimizing defect and/or void formation.

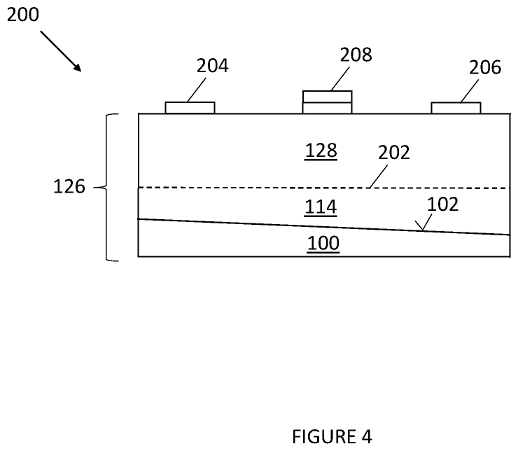

Referring to FIG. 4, silicon carbide substrate 126 formed by the above-described method may comprise a semiconductor device 200 formed therein. In the depicted embodiment, the semiconductor device 200 is a heterojunction semiconductor device, which refers to a type of semiconductor device that utilizes the advantageous properties of heterojunctions as part of the active device structure. A so-called high-electron-mobility transistor (HEMT) or heterostructure FET (HFET) is one example of such a device. This type of device uses the naturally occurring two-dimensional charge carrier gas which forms near heterojunction as an active device channel. In this case, the first SiC layer 114 of α-SiC and the second SiC layer 120 of β-SiC form a heterojunction 202 with one another, due to the different bandgap of different polytype SiC materials. The semiconductor device 200 comprises first and second device terminals 204, 206 formed in the silicon carbide substrate 126 and a gate terminal 208 arranged between the first and second device terminals 204, 206. The first and second device terminals 204, 206 may each be conductively connected with the two-dimensional charge carrier gas that forms near the heterojunction 202, with the gate terminal 208 being configured to control a conductive connection between the first and second device terminals 204, 206 in a commonly known manner.

The regions of the silicon carbide substrate 126 outside of the monocrystalline region 128 of the β-SiC and/or below the heterojunction 202 can be processed in a variety of different ways. As shown, the semiconductor device 200 does not comprise the first and second trenches 106, 108 or the defect regions 127, 130 disposed thereon. The semiconductor device 200 may correspond to an active area of a device with multiple separate regions in the silicon carbide substrate 126, wherein the defect regions 127, 130 are interposed between each region. Alternatively, the silicon carbide substrate 126 may be singulated, e.g., by mechanical cutting, etching laser application, to form discrete devices from the monocrystalline regions 128 of the β-SIC. As shown, a portion of the base substrate 100 is present in the semiconductor device 200 underneath the first SiC layer 114. The first SiC layer 114 thus comprises a lower surface that is aligned with the growth surface 102 of the base substrate 100. Thus, the first SiC layer 114 is arranged with upper and lower surfaces that diverge away from one another according to the off-axis tilt between the growth surface 102 and the first crystallographic plane. Optionally, the base substrate 100 portion may be removed, e.g., by etching, grinding, polishing, etc., such that a rear surface of the silicon carbide substrate 126 is formed in the first SiC layer 114.

Other types of semiconductor devices may be formed in the silicon carbide substrate 126 in addition to the heterojunction semiconductor device described above. In any of these devices, active device regions, e.g., source, drain, gate, etc. may be formed in the monocrystalline region 128 of the β-SiC of the semiconductor device 200, and the advantageous properties of β-SiC can be realized in such as device. Examples of these device configurations include diodes, field-effect transistors (FETs), in particular metal-oxide field effect transistors (MOSFETs), insulated gate bipolar transistors (IGBTs), junction field effect transistors (JFETs), and thyristors to name a few. These semiconductor devices may be configured as a power semiconductor device, which refers to a single device that is rated to block high voltages of at least 100V, and more commonly on the order of 250V, 500V, 600V, 1,200V, 2,000V and/or can conduct high currents of 10 A, 50 A, 100 A, 500 A or more as between two load terminals.

Although the present disclosure is not so limited, the following numbered examples demonstrate one or more aspects of the disclosure.

Example 1. A method of forming a semiconductor device, the method comprising providing a base substrate of SiC comprising a growth surface extending along a plane that is angled relative to a first crystallographic plane of the SiC from the base substrate, forming first and second trenches in the base substrate that extend from the growth surface into the base substrate, epitaxially forming a first SiC layer on the growth surface of the base substrate by a step-controlled epitaxy technique; and epitaxially forming a second SiC layer on the first SiC layer, wherein the first SiC layer is a layer of α-SiC, and wherein the second SiC layer is a layer of β-SIC.

Example 2. The method of example 1, wherein the first SiC layer is formed to comprise an upper surface that originates at a first corner of the first trench, wherein the upper surface of the first SiC layer is aligned with a first crystallographic plane of the SiC from the first SiC layer, and wherein the second SiC layer forms directly on the upper surface of the first SiC layer.

Example 3. The method of example 2, wherein the first SiC layer is formed to cover the growth surface of the base substrate in between the first and second trenches.

Example 4. The method of example 3, wherein the second SiC layer is formed to comprise a monocrystalline region of the β-SIC that is disposed directly on the upper surface of the first SiC layer and is laterally between the first and second trenches.

Example 5. The method of example 3, wherein epitaxially forming the first SiC layer forms defect regions within or above the first and second trenches.

Example 6. The method of example 3, further comprising forming an active semiconductor device in the monocrystalline region of the β-SIC.

Example 7. The method of example 6, wherein the active semiconductor device is a heterojunction device comprising a heterojunction between the first SiC layer and the second SiC layer.

Example 8. The method of example 2, wherein the step-controlled epitaxy technique grows the α-SiC in a growth direction that is parallel to the first crystallographic plane, and wherein the first trench comprises a first sidewall that is nearest to the second trench, and wherein the first sidewall extends transversely to the growth direction.

Example 9. The method of example 8, wherein the first sidewall extends at an angle that is within 30 degrees of perpendicular to the growth direction.

Example 10. The method of example 1, wherein the first SiC layer is a layer of 2H-SiC, 4H-SiC, or 6H-SiC.

Example 11, a semiconductor device, comprising a silicon carbide substrate comprising a first SiC layer and a second SiC layer formed on an upper surface of the first SiC layer, wherein the first SiC layer is a layer of α-SiC, and wherein the second SiC layer is a layer of β-SIC, and wherein the upper surface of the first SiC layer is aligned with a first crystallographic plane of the SiC from the first SiC layer.

Example 12. The semiconductor device of example 11, wherein the semiconductor device is a heterojunction device that is configured to form an electrically conductive connection between first and second device terminals via a heterojunction between the first and second SiC layers.

Example 13. The semiconductor device of example 11, wherein the second SiC layer comprises a monocrystalline region of the α-SiC that is disposed directly on the upper surface of the first SiC layer.

Example 14. The semiconductor device of example 13, wherein a lower surface of the first SiC layer extends along a plane that is tilted relative to the first crystallographic lattice plane.

Example 15. The semiconductor device of example 11, further comprising a base substrate of SiC comprising a growth surface extending along a plane that is angled relative to the first crystallographic plane, and first and second trenches extending from the growth surface of the base substrate, wherein the heterojunction between the first SiC layer and the second SiC layer extends from a first corner of the first trench, the first corner of the first trench being an intersection between the growth surface of the base substrate and a first sidewall of the first trench that is closest to the second trench.

The term “β-SiC” as used herein refers to a cubic polytype of silicon carbide, otherwise known as “3C-SiC.” The term “α-SiC” as used herein refers to all other polytypes of silicon carbide, including hexagonal polytypes and rhomboidal polytypes. The different polytypes of silicon carbide can be categorized with reference to bilayers, which are commonly referred to as the “A,” “B” and “C” bilayers. In β-SiC, otherwise known as “3C-SiC,” the Si-C bilayers stack on top of one another in an ABCABC sequence, i.e., A, then B, then C, then A, then B, then C, and so forth. Examples of α-SiC include so-called “2H-SiC,” wherein the Si-C bilayers stack on top of one another in an ABAB sequence, so-called 4H-SiC, wherein the Si-C bilayers stack on top of one another in an ABCBABCB sequence, and so-called 6H-SiC, wherein the Si-C bilayers stack on top of one another in an “ABCACBABCACB” sequence.

Spatially relative terms such as “under,” “below,” “lower,” “over,” “upper” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc. and are also not intended to be limiting. Like terms refer to like elements throughout the description.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. A method of forming a semiconductor device, the method comprising:
providing a base substrate comprising SiC and a growth surface extending along a plane that is angled relative to a first crystallographic plane of the SiC from the base substrate;
forming first and second trenches in the base substrate that extend from the growth surface into the base substrate;
epitaxially forming a first SiC layer on the growth surface of the base substrate by a step-controlled epitaxy technique; and
epitaxially forming a second SiC layer on the first SiC layer,
wherein the first SiC layer is a layer of α-SiC, and
wherein the second SiC layer is a layer of β-SiC.

2. The method of claim 1, wherein the first SiC layer is formed to comprise an upper surface that originates at a first corner of the first trench, wherein the upper surface of the first SiC layer is aligned with a first crystallographic plane of the SiC from the first SiC layer, and wherein the second SiC layer forms directly on the upper surface of the first SiC layer.

3. The method of claim 2, wherein the first SiC layer is formed to cover the growth surface of the base substrate in between the first and second trenches.

4. The method of claim 3, wherein the second SiC layer is formed to comprise a monocrystalline region of the β-SiC that is disposed directly on the upper surface of the first SiC layer and is laterally between the first and second trenches.

5. The method of claim 3, wherein epitaxially forming the first SiC layer forms defect regions within or above the first and second trenches.

6. The method of claim 3, further comprising forming an active semiconductor device in the monocrystalline region of the β-SiC.

7. The method of claim 6, wherein the active semiconductor device is a heterojunction device comprising a heterojunction between the first SiC layer and the second SiC layer.

8. The method of claim 2, wherein the step-controlled epitaxy technique grows the α-SiC in a growth direction that is parallel to the first crystallographic plane, and wherein the first trench comprises a first sidewall that is nearest to the second trench, and wherein the first sidewall extends transversely to the growth direction.

9. The method of claim 8, wherein the first sidewall extends at an angle that is within 30 degrees of perpendicular to the growth direction.

10. The method of claim 1, wherein the first SiC layer is a layer of 2H-SiC, 4H-SiC, or 6H-SiC.

11. A semiconductor device, comprising:
a silicon carbide substrate comprising a first SiC layer and a second SiC layer formed on an upper surface of the first SiC layer,
wherein the first SiC layer is a layer of α-SiC, and
wherein the second SiC layer is a layer of β-SiC, and
wherein the upper surface of the first SiC layer is aligned with a first crystallographic plane of the SiC from the first SiC layer.

12. The semiconductor device of claim 11, wherein the semiconductor device is a heterojunction device that is configured to form an electrically conductive connection between first and second device terminals via a heterojunction between the first and second SiC layers.

13. The semiconductor device of claim 11, wherein the second SiC layer comprises a monocrystalline region of the β-SiC that is disposed directly on the upper surface of the first SiC layer.

14. The semiconductor device of claim 13, wherein a lower surface of the first SiC layer extends along a plane that is tilted relative to the first crystallographic lattice plane.

15. The semiconductor device of claim 11, further comprising:
a base substrate of SiC comprising a growth surface extending along a plane that is angled relative to the first crystallographic plane; and
first and second trenches extending from the growth surface of the base substrate,
wherein the heterojunction between the first SiC layer and the second SiC layer extends from a first corner of the first trench, the first corner of the first trench being an intersection between the growth surface of the base substrate and a first sidewall of the first trench that is closest to the second trench.
